(19) United States
(12) Patent Application Publication
(10) Pub. No.: US 2012/0145243 A1
(43) Pub. Date: Jun. 14, 2012

(54) SOLAR CELLS WITH MAGNETICALLY ENHANCED UP-CONVERSION

(76) Inventors: David L. Williams, Menlo Park, CA (US); Andrew Clark, Palo Alto, CA (US); Michael Lebby, Apache Junction, AZ (US)

(21) Appl. No.: 12/965,376

(22) Filed: Dec. 10, 2010

(51) Int. Cl. H01L 31/02; H01L 31/0256

(52) U.S. Cl. 136/261; 136/252

(57) ABSTRACT

A method of magnetically enhancing up-conversion components includes providing at least one of up-conversion material and sensitizer material (i.e. up-conversion components), generally in conjunction with a semiconductor solar cell, and positioning magnetic apparatus adjacent the up-conversion components to supply a magnetic field to the up-conversion components. The magnetic field has an intensity and direction selected to enhance operation of the up-conversion components.

### FIELD OF THE INVENTION

This invention relates to up-conversion in solar cells and more particularly, to magnetically enhanced up-conversion.

### BACKGROUND OF THE INVENTION

At the present time, solar cells are primarily silicon devices because of the maturity of the silicon processing art and the fact that silicon is one of the least expensive and most abundant materials available. Further, silicon based solar cells can be easily and inexpensively integrated into silicon circuits for collection and other functions. However, it is well known in the solar cell art that most silicon solar cells are able to convert only a portion of solar energy into electricity. This is primarily due to the fact that the spectral range of Si photodiodes is confined to a wavelength range of between 200 nm and approximately 1200 nm.

In attempts to overcome the conversion drawbacks of silicon solar cells, some spectral conversion materials have been developed that absorb solar energy and reemit it in a different spectral range. Most of these spectral conversion materials provide “up-conversion” phenomena, which is the absorption of higher spectral range energy and the reemission at a lower spectral range. Thus, up-conversion materials absorb spectral energy above 1200 nm (generally around 1500 nm) and reemit it at, for example, 980 nm. Up-conversion material may be placed in proximity to the back surface of the solar cell on the front surface of the solar cell or even in some combination of the two.

Additional information on up-conversion and down-conversion materials can be found in a copending United States Patent application entitled “Photovoltaic up conversion and down conversion using rare earths”, Ser. No. 12/408,297, filed Mar. 20, 2009, (also U.S. Publication 2010/0038521) and incorporated herein by reference.

Rare earth materials are poor absorbers which has been an impediment to the adoption of rare earth up-conversion technology. Absorption by a rare earth material comes with two problems: there is both a low absorption cross section and a spectrally narrow absorption range. Thus, in some solar cells a layer of material including silicon and a blend of sensitizers is deposited so as to operate in conjunction with up-conversion materials.

Sensitizers are a material with broad absorption spectrum, e.g. from 1100 nm to 1500 nm, that can be designed to emit at approximately 1530 nm. This emission is then absorbed by the rare earth up-conversion material (e.g. Er) and up-converted to wavelengths that can be absorbed by the silicon solar cell. Additional information about sensitizers, including examples, can be found in an article entitled “Broadband sensitizers for erbium-doped planar optical amplifiers:review” by A. Polman and F. Veggel, Vol. 21, No. May 5, 2004/ J. Opt. Soc. Am. B., 871-892 and an article by J. F. Suyer et al., Optical Materials, 27 (2005), 1111-1130.

While up-conversion and sensitizers add some power and spectral conversion components to the basic amount of solar energy that silicon solar cells are able to convert, there is still only a portion of solar energy converted into electricity.

It would be highly advantageous, therefore, to remedy the foregoing and other deficiencies inherent in the prior art.

An object of the present invention is to provide magnetic enhancement of up-conversion components to improve solar cell operation. Another object of the present invention is to provide a solar cell with magnetically enhanced up-conversion material and/or sensitizers (i.e. up-conversion components) for more efficient conversion of solar energy.

Another object of the present invention is to provide a new and improved method of magnetically enhancing up-conversion components for more efficient conversion of solar energy.

### SUMMARY OF THE INVENTION

Briefly, to achieve the desired objects and aspects of the instant invention in accordance with a preferred embodiment thereof provided is a solar cell with magnetically enhanced up-conversion components. The solar cell is formed of semiconductor material and includes up-conversion components. Magnetic apparatus is positioned adjacent the back surface of the solar cell to supply a magnetic field to at least the up-conversion components. The magnetic field has an intensity and direction selected to enhance operation of the up-conversion components. Preferably the selected intensity and direction of the magnetic field is determined by trial and error.

The desired objects and aspects of the instant invention are further achieved in accordance with a preferred method of magnetically enhancing up-conversion components. The method includes providing at least one of up-conversion material and sensitizer material (i.e. up-conversion components), generally in conjunction with a semiconductor solar cell, and positioning magnetic apparatus adjacent the up-conversion components to supply a magnetic field to the up-conversion components. The magnetic field has an intensity and direction selected to enhance operation of the up-conversion components.

### BRIEF DESCRIPTION OF THE DRAWINGS

Specific objects and advantages of the instant invention will become readily apparent to those skilled in the art from the following detailed description of a preferred embodiment thereof taken in conjunction with the drawings, in which:

FIG. 1 is a graphic representation of the solar spectrum showing the curve of silicon responsivity;

FIG. 2 is a graphic representation of a typical up-conversion spectrum, in this example erbium;

FIG. 3 illustrates the hyperfine structure of an erbium ion;

FIG. 4 is a simplified view of a test set-up for a silicon solar cell with magnetically enhanced up-conversion;

FIG. 5 is a graphic representation illustrating the up-conversion spectrum of FIG. 2 and illustrating the effect of an applied magnetic field;

FIG. 6 illustrates the effects on the up-conversion spectrum of an improperly applied magnetic field;

FIG. 7 is a visualization of spin-orbit coupling of the magnetic moments of an ion as vectors in a weak magnetic B-field;

FIG. 8 is a visualization of spin-orbit coupling of the magnetic moments of an ion as vectors in a strong magnetic B-field;

FIG. 9 is a simplified view a silicon solar cell including an up-converter and typical position of a magnet for magnetic enhancement, with no cooling included;

FIG. 10 is a simplified view a silicon solar cell including an up-converter and typical position of a magnet for magnetic enhancement, with fluid cooling included;

FIG. 11 graphic representation of the solar spectrum showing the approximate wavelengths of erbium up-conversion and dysprosium sensitizer; and

FIG. 12 illustrates an energy level diagram for erbium and dysprosium.

### DETAILED DESCRIPTION OF THE DRAWINGS

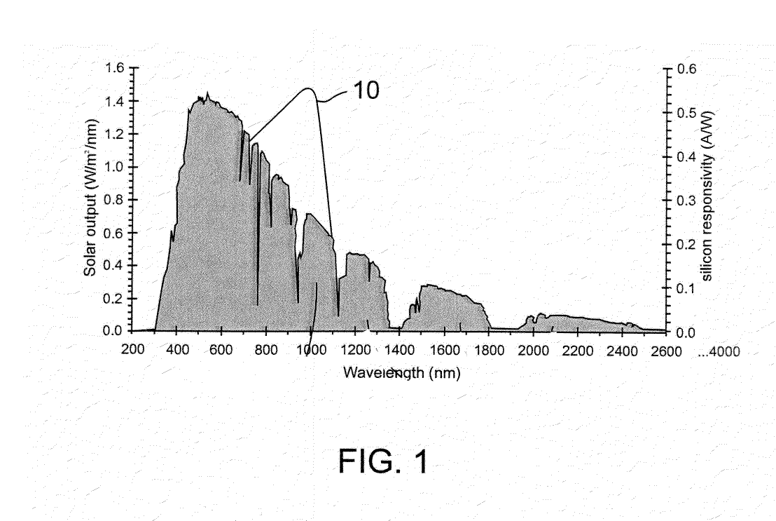

Turning now to the drawings, attention is first directed to FIG. 1, which includes a graphic representation of the solar spectrum and further shows a curve, designated 10, representing the responsivity of silicon as used in solar cells. It can be seen that the wavelengths within the solar spectrum extend from approximately 200 nm to greater than 2400 nm. It can also be seen that curve 10 representing the responsivity of silicon only extends from approximately 200 nm to the silicon cutoff bandgap at approximately 1200 nm, which is approximately 79.6% of the power density. Thus, 20.4% of the power density of the solar spectrum is not collected by silicon solar cells.

This problem can be ameliorated somewhat by including spectral conversion materials in the silicon solar cells. Spectral conversion materials have been developed that absorb solar energy and reemit it in a different spectral range. Most of these spectral conversion materials provide “up-conversion” phenomena, which is the absorption of higher spectral range energy and the reemission at a lower spectral range. Thus, up-conversion materials absorb spectral energy above 1200 nm (generally around 1500 nm) and reemit it at, for example, 980 nm. The up-conversion phenomenon is used as an example in the present invention description because it is the most commonly used material and is believed to be the most useful in the conversion of solar energy.

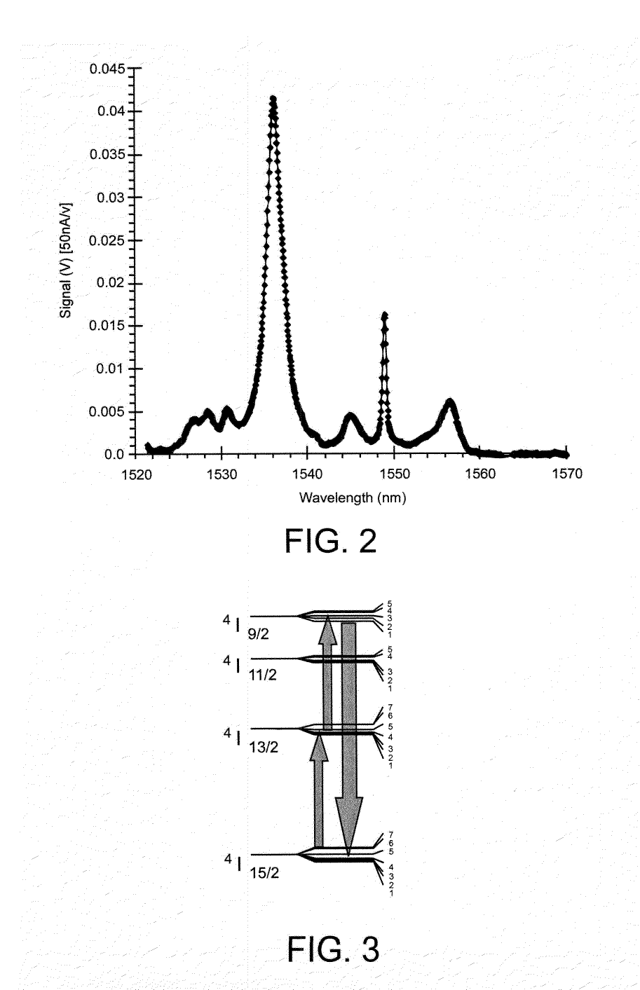

Referring additionally to FIG. 2, a graphic representation of a typical up-conversion spectrum is illustrated. In this specific example, the up-conversion spectrum of erbium is illustrated because of its general application to the conversion of solar energy in conjunction with silicon solar cells. As can be seen, the specific up-conversion material shown absorbs spectral energy in a range of approximately 1525 nm to 1558 nm with a peak between 1535 nm and 1537 nm. The absorbed spectral energy is then reemitted, for example, at approximately 980 nm, which in practice is absorbed by an adjacent silicon solar cell. Thus an additional portion of the otherwise lost solar energy is converted and absorbed to make the solar cell more efficient.

It is understood that in the excited state up-conversion, 2 long wavelength photons are absorbed and one short wavelength photon is emitted. For example, in erbium two ˜1530 nm photons are absorbed and one ˜980 nm photon is emitted. The up-conversion process depends upon the hyperfine structure of the ions forming the up-conversion material. Referring additionally to FIG. 3 the hyperfine structure of an erbium ion is illustrated along with the up-conversion process.

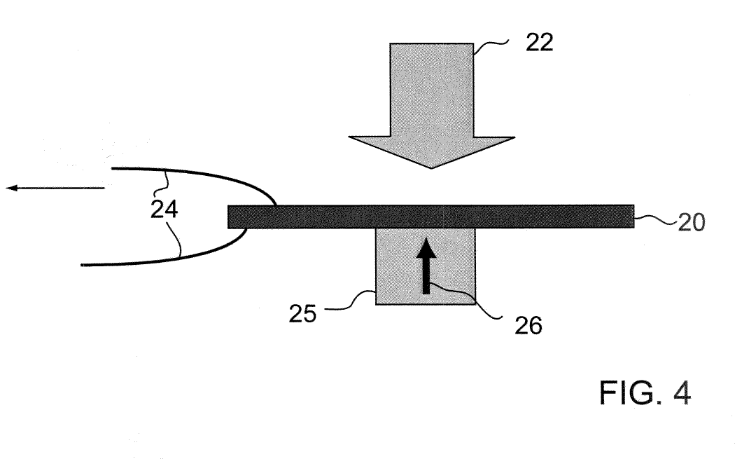

Turning now to FIG. 4, a simplified schematic representation of a test set-up for the present invention is illustrated. In this test set-up, a silicon solar cell 20 including up-conversion material (not specifically shown) is provided. It should be understood that a variety of silicon solar cells including up-conversion components can be provided, at least some of which are described in a copending United States Patent Application entitled “Solar Cells with Engineered Spectral Conversion”, filed 26 May 2010, bearing Ser. No. 12/788,285 and included herein by reference. Light 22 (generally sun light) is emitted onto a surface of solar cell 20 and a current measurement system (not shown) is connected by way of standard leads 24. A magnet 25 is positioned beneath solar cell 20 so as to apply a magnetic B-field, represented by arrow 26 to solar cell 20. While a simple permanent magnet may be used to apply the magnetic field, it will be understood that any magnetic apparatus (e.g. permanent magnet, electromagnet, etc.) may be used that will provide the desired magnetic field including both the intensity and the direction desired.

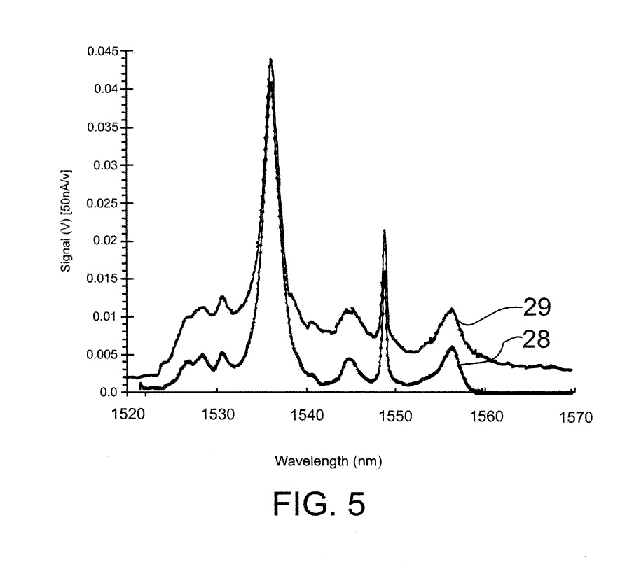

The electrical signal from solar cell 20 was measured as a function of wavelength, both with and without the presence of the magnet, i.e. the magnetic field. The up-conversion effect of the applied magnetic field is illustrated in FIG. 5 wherein the up-conversion effect with no magnetic field is represented by the line 28 and the up-conversion effect with a magnetic field is represented by the line 29. Evaluating the area under the graph shows that the magnet (i.e. the magnetic field) improves the output of solar cell 20 by a factor of 2.25×.

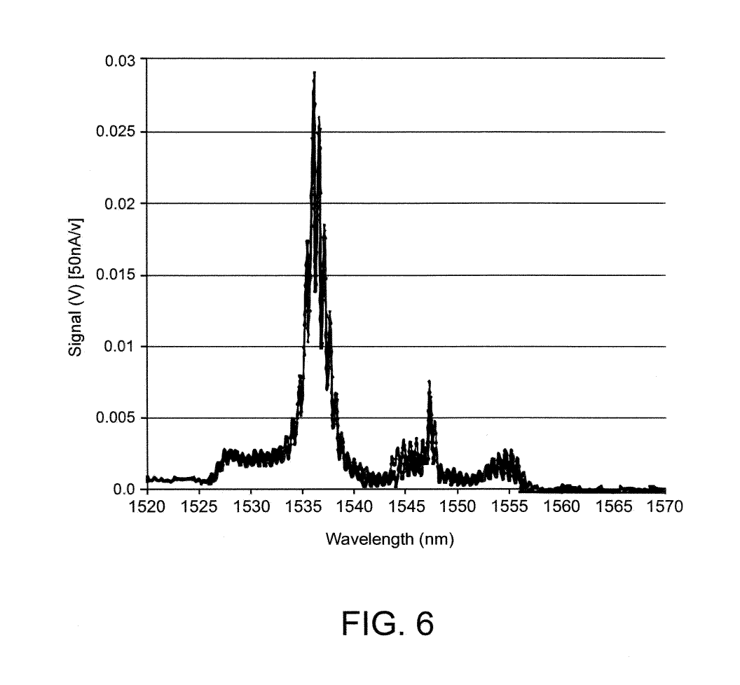

It was also found that the magnitude and direction of the magnetic field relative to the crystal orientation of the up-conversion material is important. As illustrated in FIG. 6, when the magnitude and direction of the magnetic field is improperly oriented the applied field had little effect, except for reducing one of the transitions at approximately 1545 nm. The intensity and direction of the magnetic field causes hyperfine splitting in the ions. The exact intensity and direction for each specific crystal type and orientation can be determined through extensive calculations but it has been found that a simple trial-and-error procedure (e.g. see test set-up of FIG. 4) is much quicker and easier.

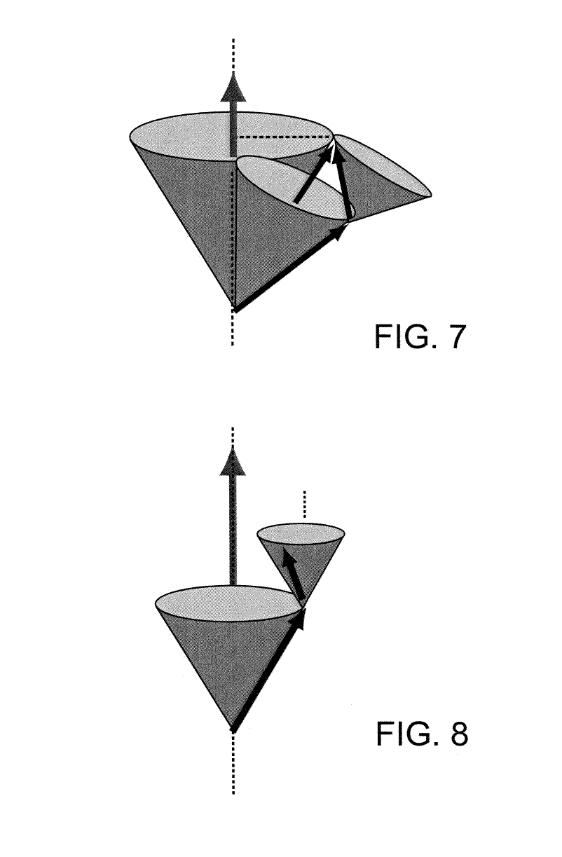

As illustrated in FIGS. 7 and 8, the magnetic moments of the up-conversion ions can be visualized as vectors with spin-orbit coupling. The visualization of spin orbit coupling in FIG. 7 illustrates how applying a weak magnetic B-field changes the hyperfine structure. The crystal field affects the local environment of the ion, as does the externally applied magnetic field. The visualization of spin orbit coupling in FIG. 8 illustrates how applying a strong magnetic B-field changes the hyperfine structure. Thus, an external magnetic field can be used to change the properties of ions, which can have a constructive and useful effect on up-conversion.

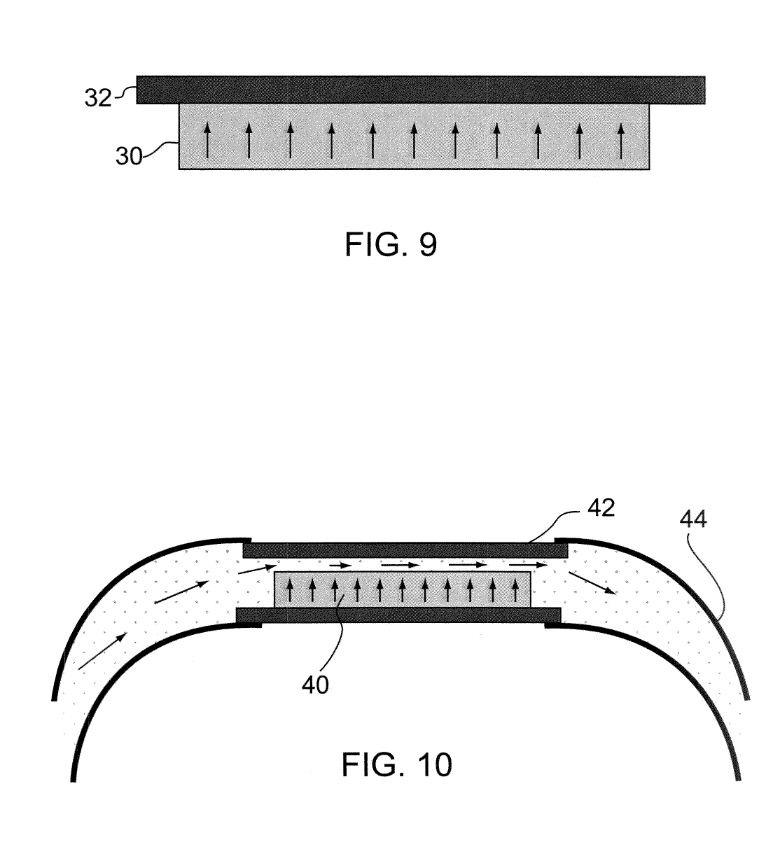

Referring to FIG. 9, one example of apparatus for applying a magnetic field to a silicon solar cell is illustrated. In this example, a magnet 30 is distributed across substantially the entire back or reverse side of a silicon solar cell 32 with included up-converter. Magnet 30 is distributed across the rear surface to supply a continuous magnetic field with a constant intensity and direction. As described above, the intensity and direction of the magnetic field for the specific crystal orientation of silicon solar cell 32 can be determined once through trial-and-error and then simply reproduced in all further solar cells. The silicon solar cell 32 and magnet 30 of this example do not use cooling of any sort, other than natural cooling.

If it is determined that some cooling would further enhance the operation of the solar cell an arrangement such as that illustrated in FIG. 10 can be used. Here a silicon solar cell 42 is incorporated into fluid conduit 44 and a magnet 40 is positioned in conduit 44 in spaced relation to solar cell 42 so that a fluid path is provided across the rear surface of solar cell 42. Conduit 44 can be attached to any fluid source (e.g. air, water, etc.) to provide a cooling flow across solar cell 42.

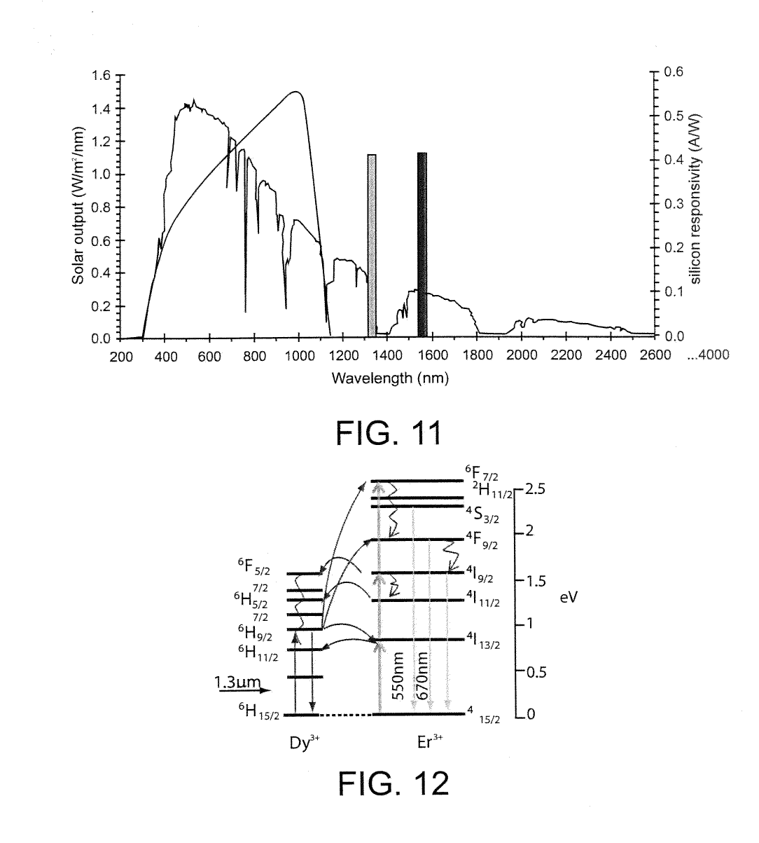

It should be understood that a variety of silicon solar cells including up-conversion material and/or sensitizers (both defined herein generically as up-conversion components) can be provided in the disclosed method and apparatus. In some solar cells a layer of material, generally including silicon and a blend of sensitizers, is deposited so as to operate in conjunction with up-conversion material. Sensitizers are a material with broad absorption spectrum, e.g. from 1100 nm to 1500 nm, that can be designed to emit at approximately 1530 nm. This emission is then absorbed by the rare earth up-conversion material (e.g. Er) and up-converted to wavelengths that can be absorbed by the silicon solar cell. Referring to FIG. 11, the spectrum of erbium as an up-conversion material and dysprosium as a sensitizer are illustrated in the solar spectrum. As can be seen, dysprosium converts additional energy from the solar spectrum into wavelengths useable by erbium. An energy level diagram for the conversion by dysprosium into energy useable by erbium and the conversion of energy by erbium into wavelengths absorbable by silicon is illustrated in FIG. 12. Various rare earths can be used to increase spectral range, either as up-converters or as sensitizers. An applied magnetic field can be used to modify the hyperfine splitting of sensitizers to make them more efficient at transferring energy to up-conversion materials. All of these materials have hyperfine structures so that magnetic fields can be applied to enhance non-radiative energy transfer between the different species.

Thus, magnetic enhancement of up-conversion components to improve solar cell operation is disclosed. A purpose of the invention is to provide magnetic enhancement of up-conversion components to improve solar cell operation. Another purpose of the present invention is to provide a solar cell with magnetically enhanced up-conversion components for more efficient conversion of solar energy. A further purpose of the present invention is to provide a new and improved method of magnetically enhancing up-conversion components for more efficient conversion of solar energy. A solar cell with magnetically enhanced spectral conversion is more efficient at converting solar energy to absorb a broader spectrum of the incident light. Also, the magnetically enhanced spectral conversion is relatively easy and inexpensive to fabricate.

Various changes and modifications to the embodiments herein chosen for purposes of illustration will readily occur to those skilled in the art. To the extent that such modifications and variations do not depart from the spirit of the invention, they are intended to be included within the scope thereof, which is assessed only by a fair interpretation of the following claims.

Having fully described the invention in such clear and concise terms as to enable those skilled in the art to understand and practice the same, the invention claimed is:

1. A solar cell with magnetically enhanced up-conversion components comprising:
a solar cell formed of semiconductor material and including up-conversion components, the solar cell including a radiation receiving front surface and a back surface; and
magnetic apparatus positioned adjacent the back surface to supply a magnetic field to at least the up-conversion components, the magnetic field having an intensity and direction selected to enhance operation of the up-conversion components.

2. A solar cell with magnetically enhanced up-conversion components as claimed in claim 1 wherein the semiconductor material includes silicon.

3. A solar cell with magnetically enhanced up-conversion components as claimed in claim 1 wherein the semiconductor material is single crystal silicon.

4. A solar cell with magnetically enhanced up-conversion components as claimed in claim 1 wherein the up-conversion components include at least one of up-conversion material and sensitizer material.

5. A solar cell with magnetically enhanced up-conversion components as claimed in claim 4 wherein the up-conversion material and sensitizer material include rare earth.

6. A solar cell with magnetically enhanced up-conversion components as claimed in claim 5 wherein the up-conversion material includes erbium and the sensitizer material includes dysprosium.

7. A solar cell with magnetically enhanced up-conversion components as claimed in claim 5 wherein the magnetic apparatus includes one of a permanent magnet and an electromagnet.

8. A solar cell with magnetically enhanced up-conversion components comprising:
a silicon solar cell including up-conversion components formed as a portion of the solar cell to provide non-radiative energy transfer between the up-conversion components and the solar cell, the solar cell having a radiation receiving front surface and a back surface; and
magnetic apparatus positioned adjacent the back surface to supply a magnetic field to at least the up-conversion components, the magnetic field having an intensity and direction selected to enhance operation of the up-conversion components.

9. A solar cell with magnetically enhanced up-conversion components as claimed in claim 8 wherein the up-conversion components include at least one of up-conversion material and sensitizer material.

10. A solar cell with magnetically enhanced up-conversion components as claimed in claim 9 wherein the up-conversion material and sensitizer material include rare earth.

11. A solar cell with magnetically enhanced up-conversion components as claimed in claim 10 wherein the up-conversion material includes erbium and the sensitizer material includes dysprosium.

12. A solar cell with magnetically enhanced up-conversion components as claimed in claim 8 wherein the magnetic apparatus includes one of a permanent magnet and an electromagnet.

13. A method of magnetically enhancing up-conversion components comprising:
providing up-conversion components including one of up-conversion material and sensitizer material; and
positioning magnetic apparatus adjacent the up-conversion components to supply a magnetic field to the up-conversion components, the magnetic field having an intensity and direction selected to enhance operation of the up-conversion components.

14. A method as claimed in claim 13 wherein the step of providing up-conversion components includes providing a semiconductor solar cell with the up-conversion components formed as a portion of the solar cell to provide non-radiative energy transfer between the up-conversion components and the solar cell.

15. A method as claimed in claim 14 wherein the step of providing the semiconductor solar cell includes providing a solar cell wherein the semiconductor material includes silicon.

16. A method as claimed in claim 13 wherein the step of providing up-conversion components including one of up-conversion material and sensitizer material includes providing up-conversion material and sensitizer material including rare earth.

17. A method as claimed in claim 16 wherein the step of providing up-conversion material and sensitizer material includes providing up-conversion material including erbium and sensitizer material including dysprosium.
